(19) United States
(12) Patent Application Publication
(10) Pub. No.: US 2022/0145448 A1
(43) Pub. Date: May 12, 2022

(54) COATED-SUBSTRATE SENSING AND CRAZING MITIGATION

(71) Applicant: Advanced Energy Industries, Inc., Fort Collins, CO (US)

(72) Inventor: Craig Rappe, Owatonna, MN (US)

(21) Appl. No.: 17/483,559

(22) Filed: Sep. 23, 2021

Related U.S. Application Data
(60) Provisional application No. 63/082,719, filed on Sep. 24, 2020.

(51) Int. Cl. C23C 14/54; C23C 14/50; C23C 14/34; C23C 14/56; G01R 19/165; G01R 15/14

(52) U.S. Cl. CPC C23C 14/54; C23C 14/50; C23C 14/3407; C03C 2218/156; G01R 19/16576; G01R 15/144; C23C 14/568

(57) ABSTRACT

Substrate coating systems and methods are disclosed. A substrate coating system comprises a deposition chamber enclosing at least a first electrode and a second electrode and a power supply coupled to the first electrode and the second electrode. The power supply is configured to apply a first voltage at the first electrode that alternates between positive and negative during each of multiple cycles to sputter target material from the electrodes onto a substrate positioned on the substrate support. A non-contact voltmeter is positioned above the substrate support to provide a sensor signal indicative of a voltage of a layer of the sputtered target material without mechanically contacting the layer, and a controller is configured to receive the sensor signal from the non-contact voltmeter and at least one of provide an alarm or adjust an application of power to the first and second electrodes in response to the signal.

### CLAIM OF PRIORITY UNDER 35 U.S.C. § 119

The present Application for Patent claims priority to Provisional Application No. 63/082,719 entitled “COATED-SUBSTRATE SENSING AND CRAZING MITIGATION” filed Sep. 24, 2020, and assigned to the assignee hereof and hereby expressly incorporated by reference herein.

### BACKGROUND

### Field of the Disclosure

The present disclosure relates generally to substrate coating, and more specifically to systems, methods, and apparatus that reduce crazing in thin film coatings applied to substrates, for instance glass substrates.

### Description of Related Art

Glass sheets and other substrates can be coated with a stack of transparent, metal and dielectric-containing films to vary the optical properties of the coated substrates. Particularly desirable are coatings characterized by their ability to readily transmit visible light while minimizing the transmittance of other wavelengths of radiation, especially radiation in the infrared spectrum. These characteristics are useful for minimizing radiative heat transfer without impairing visible transmission. Coated glass of this nature is useful in architectural and automotive applications.

For instance, coatings having the characteristics of high visible transmittance and low emissivity typically include one or more infrared-reflective films and two or more antireflective transparent dielectric films. The infrared-reflective films, which are typically conductive metals such as silver, gold, or copper, reduce the transmission of radiant heat through the coating. The transparent dielectric films are used primarily to reduce visible reflection, to provide mechanical and chemical protection for the sensitive infrared-reflective films, and to control other optical coating properties, such as color. Commonly used transparent dielectrics include oxides of zinc, tin, and titanium, as well as nitrides of silicon, chromium, zirconium, and titanium. Low-emissivity coatings are commonly deposited on glass sheets through the use of well-known magnetron sputtering techniques.

The technique, sometimes referred to as magnetron sputtering, involves the formation of a plasma which is contained by a magnetic field and which serves to eject atoms from an adjacent metal target, the metal atoms being deposited upon an adjacent surface such as the surface of a glass pane. When sputtering is done in an atmosphere of an inert gas such as argon, the metal alone is deposited whereas if sputtering is done in the presence of oxygen, e.g., in an atmosphere of argon and oxygen, then the metal is deposited as an oxide. Magnetron sputtering techniques and apparatuses are well known and need not be described further.

Plasma chemical vapor deposition involves decomposition of gaseous sources via a plasma and subsequent film formation onto solid surfaces, such as glass substrates. The deposition rate and thickness of the resulting film can be adjusted by varying the transport speed of the substrate as it passes through a plasma zone and by varying the power and gas flow rate within each zone.

Sputtering techniques and equipment are well known in the art. For example, magnetron sputtering chambers and related equipment are commercially available from a variety of sources

To produce the multi-layer glass coatings described above, a common processing technique is used where a slab of glass (e.g., up to twelve feet on a side) moves through a plurality of plasma deposition chambers continuously by means of a conveyor belt or other substrate support. Each deposition chamber includes one or more sputtering targets and a power supply such that as the glass passes through each chamber, a different thin film layer is deposited. While passing through a series of dozens of chambers, a slab of glass can be quickly and homogeneously coated with dozens of thin film layers.

In some cases, especially where combinations of alternating dielectric and conductor layers are used, crazing (sometimes referred to as “lightning arc” defects) near the edges of the deposited can occur, and such problems have plagued manufacturers since at least the 1970's. As shown in FIG. 1, crazing involves a defect in the coatings that appears similar to a lightning strike, and hence, the reference to “lightning arc” defect. In many cases, these defects may ruin a slab of glass rendering it unusable, especially when they cover a significant portion of the glass's surface area or extend inwards from the edges. There have been many attempts over the last half century to understand the source of crazing and try to minimize its effects, however crazing continues to plague many glass coaters. Thus, there is a need in the art for systems and methods of glass coating that can predict and reduce crazing of sputtered thin films.

### SUMMARY

An aspect may be characterized as a substrate coating system comprising a deposition chamber enclosing at least a first electrode and a second electrode, a substrate support within the deposition chamber, and a power supply coupled to the first electrode and the second electrode. The power supply is configured to apply a first voltage at the first electrode that alternates between positive and negative relative to the second electrode during each of multiple cycles to sputter target material from the electrodes onto a substrate positioned on the substrate support, and a non-contact voltmeter positioned above the substrate support to provide a sensor signal indicative of a voltage of a layer of the sputtered target material without mechanically contacting the layer. A controller is configured to receive the sensor signal from the non-contact voltmeter and at least one of provide an alarm or adjust an application of power to the first and second electrodes in response to the signal.

Another aspect may be characterized as a method for processing a substrate. The method comprises depositing a plurality of layers on to the substrate with a substrate coating system, monitoring a voltage at a surface of each of the layers, and at least one of providing an alarm or controlling an application of power to the substrate coating system in response to the voltage monitoring.

Yet another aspect may be characterized as a non-transitory, tangible processor readable storage medium, encoded with processor executable instructions to perform a method for processing a substrate. The instructions comprise instructions for controlling a substrate coating system to deposit a plurality of layers on to the substrate, monitoring a voltage at a surface of each of the layers, and at least one of providing an alarm or controlling an application of power to the substrate coating system in response to the voltage monitoring.

### BRIEF DESCRIPTION OF THE DRAWINGS

FIG. 1 is a depiction of defects known to occur in coatings deposited on a substrate;

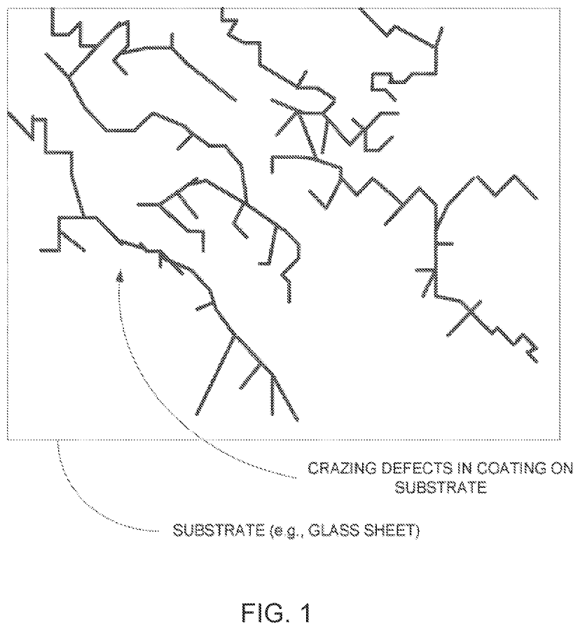

FIG. 2 is a side view of a portion of a substrate coating system;

FIG. 3 is a top view of the substrate coating system of FIG. 3;

FIG. 4 is a view along section A-A of FIG. 3;

FIG. 5 is a schematic representation of an example of a non-contact voltmeter;

FIG. 6 is a flowchart depicting a method that may be traversed in connection with embodiments disclosed herein; and

FIG. 7 is a block diagram depicting an example of components that may be used in a controller.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

For the purposes of this disclosure, a plasma sputtering chamber and a plasma deposition chamber will be used interchangeably. For the purposes of this disclosure a substrate can be a glass substrate, such as architectural glass, display technology glass (e.g., laptop and TV screens), or any other substrate upon which thin film coatings can be deposited.

For the purposes of this disclosure, an insulator can include dielectrics and oxides among other insulators. For the purposes of this disclosure, a conductor can include metals and other conductive materials, as well as semiconductors. For instance, the conductor layers described below can include metals such as silver, aluminum, or tungsten, to name three non-limiting examples.

For the purposes of this disclosure, crazing (or lighting arcs) is the defect in conductive thin film layers caused when one or more dielectric insulating layers between the conductive thin films breaks down.

As noted above, many attempts have been made to understand and reduce crazing. For instance, some believe that strong electric fields that can build near the edge of the substrate will cause crazing events and have therefore implemented procedures to bevel the edges of the glass. But beveling can add significant time and cost to the manufacturing process in terms of both labor and mechanical setup. It should also be noted that implementation of a beveling step can improve the crazing defect rate, but it typically does not reduce this rate to zero.

Others have tried grounding the glass during processing by providing a ground path between a top surface of the glass and ground via a lead or probe which touches the passing glass slab. But the grounded glass surface may lead to poor deposition characteristics, and in some cases, the ground lead induces its own defects in the coatings; thus, grounding the glass has proven unsatisfactory.

Yet others, noting that crazing is less common after a chamber has been cleaned, have attempted to perform frequent chamber cleanings. But such frequent cleanings require the chamber vacuum to be removed and then returned; thus, causing unacceptable loss in throughput.

Still others have looked at a differential voltage between electrodes in a single plasma deposition chamber but have been unable to observe any electrical anomalies correlated with arcing, which is believed to be one possible mechanism responsible for crazing. Some, believing that coupling between nearby processing chambers in the processing line leads to crazing, have worked to isolate plasmas in adjacent chambers (e.g., by providing a separate vacuum pump for each chamber). While this may have reduced electrical coupling between plasmas in adjacent chambers, it did not improve crazing rates.

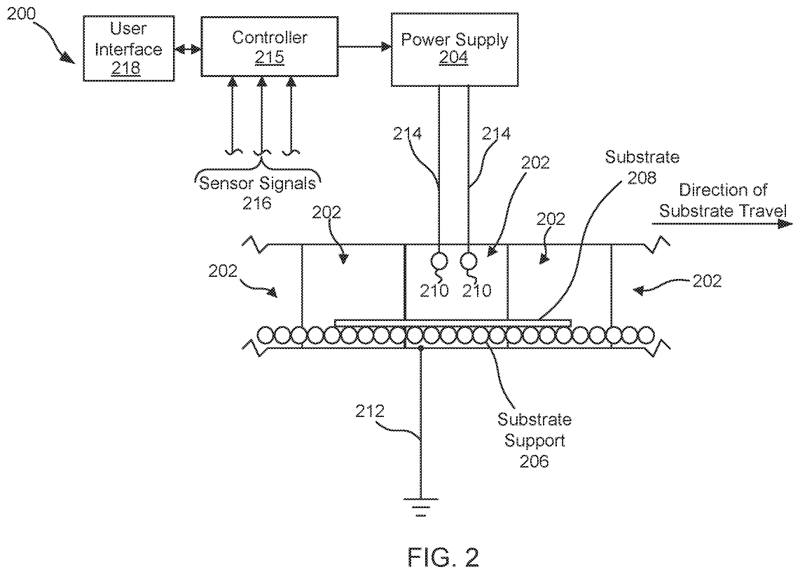

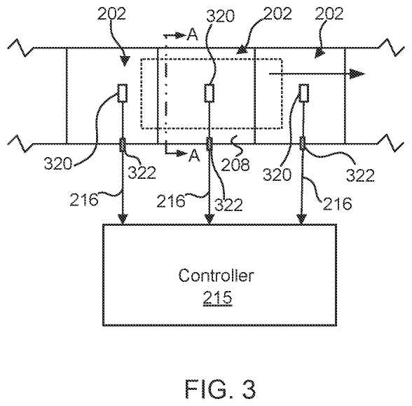

FIGS. 2 and 3 illustrate side and top views, respectively, of a subsection of a substrate coating system 200 having a plurality of deposition chambers 202 arranged in a sequential processing line for sputtering. For simplicity, only a single power supply 204 is depicted in FIG. 2, but it should be recognized that each deposition chamber 202 may be associated with a corresponding power supply 204, which may be realized by AC or bipolar DC power sources (such as the CRYSTAL AC Power Supply or ASCENT AMS/DMS power supply system manufactured by Advanced Energy, Fort Collins, Colo.). It should also be recognized, as depicted in FIG. 2, that each of the power supplies 204 may be coupled to a corresponding pair of electrodes 210 that are enclosed by a corresponding deposition chamber 202. The deposition chambers 202 may be configured to deposit insulators, conductors, or other materials. The substrate coating system 200 may also comprise a substrate support 206, such as a conveyor (e.g., a roller conveyor) that is arranged span across a plurality of deposition chambers 202 through the substrate coating system 200. The substrate support 206 is configured to pass or convey a substrate 208 through the deposition chambers 202 so the deposition chambers 202 can continuously deposit thin films as the substrate 208 passes sequentially through each chamber. The substrate 208 is often, but not always, sized such that it spans more than one chamber at a time. Here, the substrate 208 spans three chambers, so it is exposed to deposition of three different thin film layers at the same time, which may cause a direct electrical connection between three plasmas. But each deposition chamber 202 is likely depositing films at different locations on the substrate 208 at any given moment. In some cases, there may be ‘overspray’ from one chamber 202 to the next chamber 202, so the previous statement may not always be true.

As shown, each power supply 204 can be coupled to two or more electrodes 210 that are enclosed by deposition chamber 202. Where two electrodes 210 are used with each power supply 204, the pair of electrodes 210 can be an anodeless pair—meaning each electrode 210 alternately functions as a cathode and anode, depending on the AC cycle of the power supply 204. In anodeless implementations, the power supply 204 may be configured to apply a first voltage at a first electrode (of the pair of electrodes 210) that alternates between positive and negative relative to a second electrode (of the pair of electrodes 210) during each of multiple cycles to sputter target material from the electrodes 210 onto the substrate 208. The power supply 204 can be coupled to, and provide power to, the electrodes 210 via connections 214. The connections 214 can be embodied in a single cable, such as a coaxial cable or triaxial cable, or in pairs of cables, wires, or leads.

The power supply 204, connections 214, and electrodes 210 can take a variety of shapes, form, and arrangements without departing from this disclosure. For instance, the electrodes 210 can be cylindrical or cubic, to name just two non-limiting examples. The electrodes 210 can also be arranged and in contact with sides of the deposition chamber 202 or can be largely separated from the chamber 202 walls as illustrated (of course some support structure that couples to the chamber 202 walls will typically be used, but the majority of the electrodes 210 are not in contact with the chamber 202 in this embodiment).

Each power supply 204 may be used with a corresponding deposition chamber 202 to deposit conductive, insulating, and/or dielectric material (e.g., various oxides) in a film on the substrate 208. Given the illustrated position of the substrate 208 in FIG. 2, a film may be deposited above one or more other films and below one or more other films, but the number of layers may generally be one or more layers and the number of deposition chambers 202 should not be limited by the depiction in FIGS. 2 and 3.

The power supply 204 and its electrodes 210 are illustrated as electrically floating, or floating, so the voltage on the electrodes 210 and output by the power supply 204 is not referenced to ground. In other embodiments, the power supply 204 can be referenced to ground. The illustrated deposition chamber 202 is grounded via grounding connection 212. Where the deposition chambers 202 in the substrate coating system 200 are conductively coupled, only a single grounding connection 212 for the entire substrate coating system 200 may be needed, although more than this can be implemented.

The substrate support 206 can be grounded, or electrically connected to the deposition chambers 202 or the grounding connection 212. Alternatively, the substrate support 206 can be floating. In this and subsequent figures, the substrate support 206 is assumed to be grounded.

In this and subsequent figures, the direction of travel of the substrate 208 is to the right of the page, but this is illustrative only, and one of skill in the art will recognize that these figures are equally applicable to substrates passing from right to left.

Although not illustrated, the deposition chamber 202 may also comprise devices and components commonly seen in plasma deposition chambers such as magnets and sputtering targets. For example, the electrodes 210 may be realized by magnetrons, but for simplicity, these common and well-known features have not been illustrated and will not be discussed.

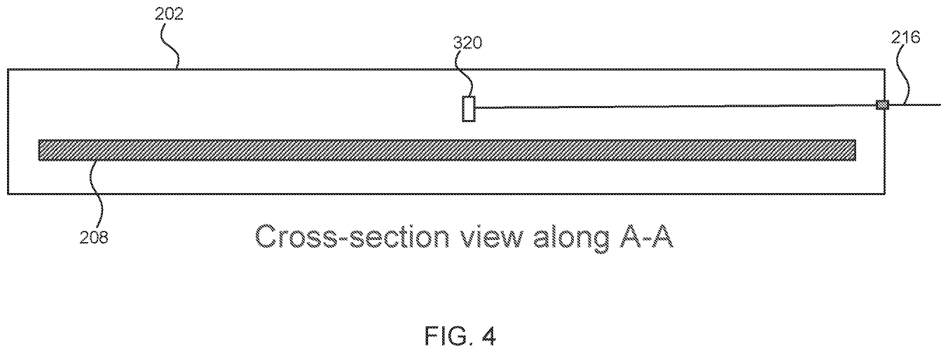

Also shown in FIGS. 2 and 3 is a controller 215 that is configured to receive sensor signals 216 from one or more sensors that are associated with the deposition chambers 202. For example, the sensors may be non-contact sensors 320 as shown in FIG. 3 and FIG. 4 (which depicts a cross-section view along section A-A of FIG. 3). More specifically, the non-contact sensors 320 may comprise one or more non-contact voltmeters positioned above the substrate support to provide a sensor signal 216 indicative of a voltage of a layer of the sputtered target material without mechanically contacting the layer. As shown, the controller 215 may be coupled to a user interface 218, which enables an operator of the substrate coating system 200 to control aspects of the power supplies 204 and receive information (e.g., conveyed by the sensor signals 216) about one or more aspects of the substrate coating system 200.

As shown in FIG. 3, n non-contact sensors 320 may be utilized to provide an indication of a voltage of each of a number of i layers deposited on the substrate 208. For example, where n=i, each of the non-contact sensors 320 may provide an indication of a surface voltage of a corresponding layer deposited on the substrate 208. It is also contemplated that (where n>i) there may be multiple sensors positioned in a deposition chamber 202 to obtain the voltage at a surface of a layer. It is also possible that (where n<i) the voltage of one or more layers does not need to be monitored. Thus, the depiction of three non-contact sensors 320 in FIG. 3 is merely an example, and generally n non-contact sensors 320 (where n is one or more) may be utilized to provide n voltage measurements.

In many embodiments, the non-contact sensors 320 are realized by non-contact voltmeters that are configured to obtain a voltage of a surface of an outermost one of the i layers in the deposition chamber 202 where the non-contact sensor 320 is located. It should be recognized that the non-contact sensors 320 are depicted as functional blocks, and as one of ordinary skill in the art will appreciate, when implemented by non-contact voltmeters, each non-contact sensor 320 may comprise a probe in connection with processing circuitry, and the processing circuitry may be located outside of the deposition chambers 202. The processing circuitry may be integrated into a common housing or distributed between multiple components including the controller 215.

As shown, the non-contact sensors 320 may be coupled to one or more controllers 215 that may be used to control aspects of power applied to the deposition chamber(s) 202 and/or may provide one or more alarms. With this data, operators of the substrate coating system 200 can receive a warning and know exactly which layer is at risk and make appropriate system adjustments. Moreover, the ability to detect surface charge on the substrate at n interfaces for the layers enables subsequent mitigation of this defect.

Referring to FIG. 4, shown is a cross-section view along section A-A of FIG. 3. As depicted each non-contact sensor 320 may be positioned above a top layer (that has been deposited on the substrate 208) and a signal line from each sensor 320 may feed through a vacuum-rated feedthrough 322 to the controller 215.

With the detection of surface voltages, the impedance of layers deposited on the substrate may be calculated. In addition, the calculation of anode impedance may be possible. It is also contemplated that closed loop control for metal layers may be performed with feedback from one or more non-contact sensors 320. Moreover, arc detection circuits known in the art may be activated to remove surface charge.

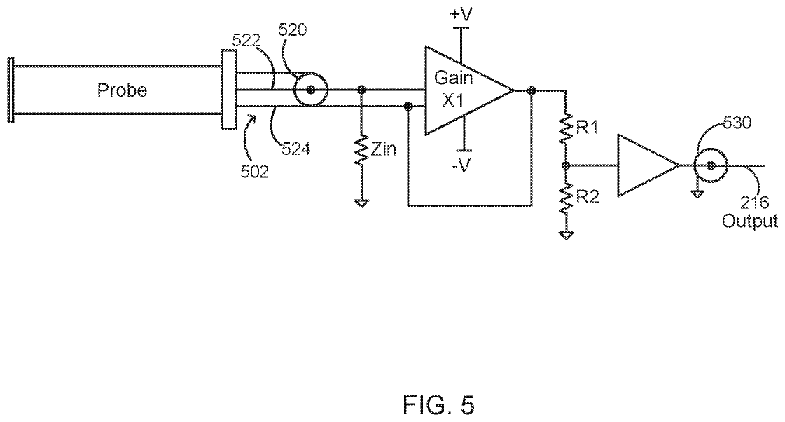

Referring next to FIG. 5, shown is an exemplary embodiment of a non-contact voltmeter implemented by an electrostatic voltmeter (ESVM). As shown, the ESVM in this embodiment includes a connector 520 (e.g., a subminiature version C (SMC) connector) to conductively couple an amplifier within the ESVM to a cable 502, which includes an inner conductor 522 and an outer conductor 524. As shown, an impedance control resistor may be coupled between the center conductor 522 and ground. The impedance control resistor may be a high value resistor that is used to match an input impedance of the ESVM to the impedance presented to the ESVM by the cable 502. An exemplary range of values of the impedance control resistor is from 1M ohms to 100 T ohms. The amplifier of the ESVM may be configured to amplify the monitored voltage in a 1:1 ratio in range from −V to +V where V may be set depending upon the particular application. For example, the rails of the ESVM may be +/−1V in some implementations and may be +/−100V in other implementations.

As shown, the output of the amplifier of the ESVM feeds to a voltage divider (implemented by resistors R1 and R2) that effectuates a reduced voltage at the input of a simple buffer that, in turn, provides sensor signal 216 to an output connector 530 (e.g., SMC connector). For example, in implementations where the rails of the ESVM are +/−100V, the sensor signal 216 may be a scaled down signal (e.g., ±10V). The sensor signal 216 is indicative of a signal on the cable 502 produced by the probe in response to the voltage at a surface layer of the substrate 208. As a consequence, the sensor signal 216 is indicative of the voltage a surface layer of the substrate 208. The sensor signal 216 may then be sampled, converted to a digital signal, and then utilized by the controller 215.

It should be recognized that FIG. 5 provides only an example of a non-contact sensor 320 and that other non-contact sensor designs may be used. Another example of an electrostatic voltmeter is described in U.S. Pat. No. 4,797,620, which is incorporated herein by reference in its entirety. Yet another example, of a non-contact sensor 320 is a TREK 370 brand ESVM. But these are merely examples and other types (and other brands) of non-contact sensors 320 may be utilized.

As those of ordinary skill in the art will readily appreciate, non-contact voltmeters are a different type of sensing technology than Langmuire probes, which are typically utilized for measuring plasma-related parameters such as electron temperature, electron density, and electron potential.

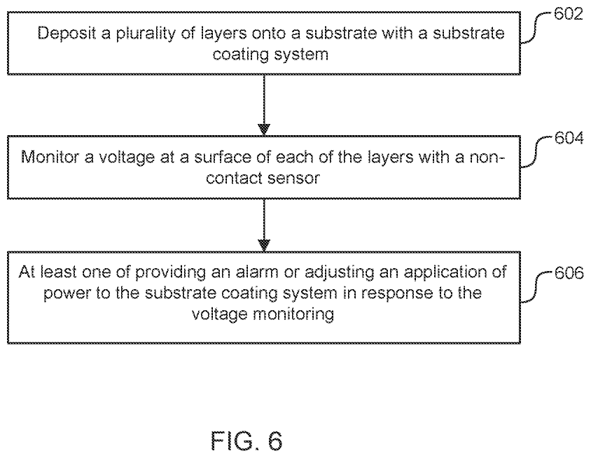

Referring next to FIG. 6, shown is a flowchart depicting a method that may be traversed in connection with embodiments disclosed herein. As shown, a plurality of layers are deposited onto a substrate with the substrate coating system 200 (Block 602). For example, the layers may be deposited by moving the substrate sequentially through each of a plurality of deposition chambers, wherein each deposition chamber deposits a corresponding one of the plurality of the layers onto the substrate. In addition, and a voltage at the surface of each of the layers is monitored with a non-contact sensor (Block 604). In response to the voltage monitoring, at least one of an alarm is provided or an application of power to the substrate coating system is adjusted (Block 606). For example, the controller 215 may provide an alarm or adjust an application of power to a particular deposition chamber 202 in response to a corresponding sensor signal 216 indicating a corresponding layer deposited by the particular layer may exceed a voltage threshold. In addition, the use of a non-contact voltmeter may generate data to indicate which metal layer is at/near or beyond a voltage saturation level on the surface of the substrate relative to system impedances.

With this data, an operator of the system can receive a warning and know exactly which layer is at risk and make appropriate system adjustments. For example, a level of charge may be controlled by triggering, in response to a level of charge exceeding a threshold, an arc management system of one or more of the power supplies 204 that apply power to the substrate coating system. It is also contemplated that an impedance of one or more of the plurality of layers may be determined in order to analyze the layers and/or as a threshold parameter to discharge one or more of the layers. Moreover an electrode impedance of one or more of the electrodes 210 may be calculated and monitored.

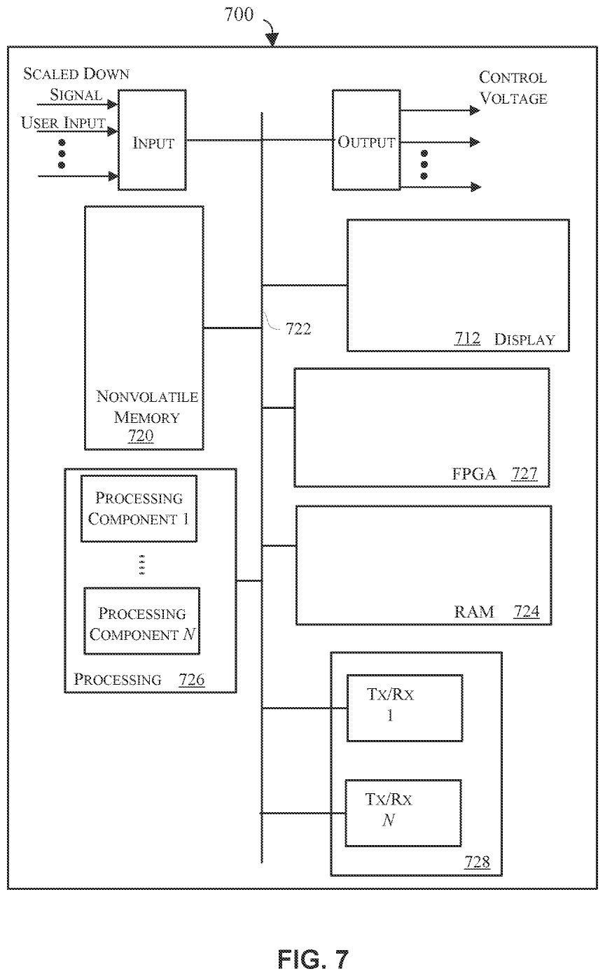

The methods described in connection with the embodiments disclosed herein may be embodied directly in hardware, in processor executable instructions encoded in non-transitory and tangible machine (e.g., processor) readable medium, or as a combination of the two. Referring to FIG. 7 for example, shown is a block diagram depicting physical components of an exemplary controller 700 that may be utilized to realize the controller described with reference to FIGS. 2 and 3. As shown, a display 712 and nonvolatile memory 720 are coupled to a bus 722 that is also coupled to random access memory (“RAM”) 724, a processing portion (which includes N processing components) 726, a field programmable gate array (FPGA) 727, and a transceiver component 728 that includes N transceivers. Although the components depicted in FIG. 7 represent physical components, FIG. 7 is not intended to be a detailed hardware diagram; thus, many of the components depicted in FIG. 7 may be realized by common constructs or distributed among additional physical components. Moreover, it is contemplated that other existing and yet-to-be developed physical components and architectures may be utilized to implement the functional components described with reference to FIG. 7.

The display 712 generally operates to provide a user interface for a user, and in several implementations, the display 712 is realized by a touchscreen display. For example, display 712 can be used to control and interact with voltmeters (e.g., ES VMs) and the controller. For example, the display 712 may display the voltage(s) of layer(s) that have been deposited on the substrate and may enable a user to configure a response to certain voltages. For example, a user may configure the controller 215 to respond by adjusting the power supply(s) 204 and/or respond by initiating a charge clearing process to remove charge from a layer. In general, the nonvolatile memory 720 is non-transitory memory that functions to store (e.g., persistently store) data and machine readable (e.g., processor executable) code (including executable code that is associated with effectuating the methods described herein). In some embodiments, for example, the nonvolatile memory 720 includes bootloader code, operating system code, file system code, and non-transitory processor-executable code to facilitate the execution of the methods described herein.

In many implementations, the nonvolatile memory 720 is realized by flash memory (e.g., NAND or ONENAND memory), but it is contemplated that other memory types may also be utilized. Although it may be possible to execute the code from the nonvolatile memory 720, the executable code in the nonvolatile memory is typically loaded into RAM 724 and executed by one or more of the N processing components in the processing portion 726.

In operation, the N processing components in connection with RAM 724 may generally operate to execute the instructions stored in nonvolatile memory 720 to realize aspects of the functionality of the controller. For example, non-transitory processor-executable instructions to effectuate the methods described herein may be persistently stored in nonvolatile memory 720 and executed by the N processing components in connection with RAM 724. As one of ordinary skill in the art will appreciate, the processing portion 726 may include a video processor, digital signal processor (DSP), graphics processing unit (GPU), and other processing components.

In addition, or in the alternative, the field programmable gate array (FPGA) 727 may be configured to effectuate one or more aspects of the methodologies described herein. For example, non-transitory FPGA-configuration-instructions may be persistently stored in nonvolatile memory 720 and accessed by the FPGA 727 (e.g., during boot up) to configure the FPGA 727 to effectuate the functions of the controller 215.

In general, the input component functions to receive analog and/or digital signals that may be utilized by the controller 700 as described herein. It should be recognized that the input component may be realized by several separate analog and/or digital input processing chains, but for simplicity, the input component is depicted as a single functional block. In operation, the input component may operate to receive signals (e.g., signals from voltmeter(s)) that are indicative of the voltage of the layer(s) on the substrate. As shown, the input component may also receive a user input to enable the user to control charge mitigation components and/or the voltmeters. The output component generally operates to provide one or more analog or digital signals to effectuate one or more operational aspects of the voltmeters, power control, and/or the charge-mitigation components.

The depicted transceiver component 728 includes N transceiver chains, which may be used for communicating with external devices via wireless or wireline networks. Each of the N transceiver chains may represent a transceiver associated with a particular communication scheme (e.g., WiFi, ethernet, universal serial bus, profibus, etc.).

In yet alternative implementations, the controller 215 may be realized by a microcontroller or an application-specific integrated circuit.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein. As used herein, the recitation of “at least one of A, B and C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A substrate coating system comprising:
a deposition chamber enclosing at least a first electrode and a second electrode;
a substrate support within the deposition chamber;
a power supply coupled to the first electrode and the second electrode, the power supply configured to apply a first voltage at the first electrode that alternates between positive and negative relative to the second electrode during each of multiple cycles to sputter target material from the electrodes onto a substrate positioned on the substrate support;
a non-contact voltmeter positioned above the substrate support to provide a sensor signal indicative of a voltage of a layer of the sputtered target material without mechanically contacting the layer; and
a controller configured to receive the sensor signal from the non-contact voltmeter and at least one of: provide an alarm or adjust an application of power to the first and second electrodes in response to the signal.

2. The substrate coating system of claim 1 further comprising:
a plurality of deposition chambers, wherein the substrate support comprises a conveyer that spans across the plurality of deposition chambers and each deposition chamber deposits a layer on the substrate to produce a plurality of layers;
a plurality of power supplies, each of the power supplies is coupled to a corresponding pair of electrodes that are enclosed by a corresponding deposition chamber; and
at least one non-contact voltmeter in each of the deposition chambers to provide a corresponding sensor signal indicative of a voltage of one of the layers, wherein the controller is configured to receive the sensor signals from the non-contact voltmeters and at least one of: provide an alarm or adjust an application of power to a particular deposition chamber in response to a corresponding sensor signal indicating a corresponding layer deposited by the particular layer may exceed a voltage threshold.

3. The substrate coating system of claim 2, wherein the controller is configured to calculate an impedance of each of the layers.

4. The substrate coating system of claim 2, wherein the controller is configured to calculate an impedance of one or more of the electrodes.

5. The substrate coating system of claim 1, wherein the non-contact voltmeters comprise electrostatic voltmeters.

6. A method for processing a substrate comprising:
depositing a plurality of layers on to the substrate with a substrate coating system;
monitoring a voltage at a surface of each of the layers; and
at least one of providing an alarm or controlling an application of power to the substrate coating system in response to the voltage monitoring.

7. The method of claim 6 comprising:
moving the substrate sequentially through each of a plurality of deposition chambers, wherein each deposition chamber deposits a corresponding one of the plurality of the layers onto the substrate.

8. The method of claim 6, wherein the voltage monitoring indicates a voltage saturation of one or more of the layers.

9. The method of claim 6 comprising:
triggering, in response to a level of charge exceeding a threshold, an arc management system of one or more power supplies that apply power to the substrate coating system.

10. The method of claim 6 comprising:
determining, using the monitored voltage, an impedance of one or more of the plurality of layers.

11. The method of claim 6 comprising:
determining, using the monitored voltage, an electrode impedance.

12. A non-transitory, tangible processor readable storage medium, encoded with processor executable instructions to perform a method for processing a substrate, the instructions comprising instructions for:
controlling a substrate coating system to deposit a plurality of layers on to the substrate;
monitoring a voltage at a surface of each of the layers; and
at least one of providing an alarm or controlling an application of power to the substrate coating system in response to the voltage monitoring.

13. The non-transitory, tangible processor readable storage medium of claim 12, wherein the instructions include instructions for voltage monitoring to determine whether a voltage saturation of one or more of the layers.

14. The non-transitory, tangible processor readable storage medium of claim 12 wherein the instructions comprise instructions for triggering, in response to a level of charge exceeding a threshold, an arc management system of one or more power supplies that apply power to the substrate coating system.

15. The non-transitory, tangible processor readable storage medium of claim 12 comprising:
determining, using the monitored voltage, an impedance of one or more of the plurality of layers.
